(19) United States
(12) Patent Application Publication
(10) Pub. No.: US 2008/0173979 A1
(43) Pub. Date: Jul. 24, 2008

(54) Semiconductor device with leaning storage node contact and method for fabricating the same

(75) Inventor: Buem-Suck Kim, Kyoungki-do (KR)

Correspondence Address: BLAKELY SOKOLOFF TAYLOR & ZAFMAN LLP, 1279 OAKMEAD PARKWAY, SUNNYVALE, CA, 94085-4040, US

(73) Assignee: Hynix Semiconductor Inc.

(21) Appl. No.: 11/985,489

(22) Filed: Nov. 15, 2007

(30) Foreign Application Priority Data
Jan. 24, 2007 (KR) 2007-0007497

(51) Int. Cl. H01L 21/441; H01L 29/92

(52) U.S. Cl. 257/532; 438/673; 257/E21.477; 257/E29.342

(57) ABSTRACT

A method for fabricating a semiconductor device including preparing a substrate provided with a first storage node contact, forming a second storage node contact over the first storage node contact, the second storage node contact leaning to one side, and forming a storage node of a capacitor over the second storage node contact.

### CROSS-REFERENCE TO RELATED APPLICATIONS

The present invention claims priority of Korean patent application number 2007-0007497, filed on Jan. 24, 2007, which is incorporated by reference in its entirety.

### BACKGROUND OF THE INVENTION

The present invention relates to a method for fabricating a semiconductor device, and more particularly, to a semiconductor device with a storage node contact and a method for fabricating the same.

Recently, as semiconductor devices are highly integrated, demands for more precise process control are increasing in fabricating semiconductor devices due to reduction in design rule. Particularly, in dynamic random access memories (DRAMs), more and more interests are being focused on a process of forming a storage node contact (SNC) for connecting an active region of a substrate to a capacitor.

If a capacitor is formed over a typical SNC, a bridge frequently occurs between storage nodes of adjacent capacitors. Therefore, there is a limitation in a method of increasing capacitance by increasing areas of capacitor electrodes.

To prevent such a bridge between storage nodes of capacitors, various layouts have recently been suggested, of which one is a shifted storage node (SSN) structure in which additional storage node contact, ‘SNC2’, is used. That is, a first storage node contact SNC1 and a second storage node contact SNC2 are used in the SSN structure. In this case, it is possible to shift a storage node to a certain distance because of employing the second storage node contact SNC2 in addition to the first storage node contact SNC1, which is significantly different from the case of employing only one storage node contact, thus preventing a bridge between storage nodes in some cases.

The first storage node contact SNC1 is connected to a substrate (an active region or a landing plug contact), and the second storage node contact SNC2 is disposed between the first storage node contact SNC1 and a storage node SN of the capacitor. Here, the second storage node contact SNC2 is offset from the center of the first storage node contact SNC1, that is, misaligned with the first storage node contact SNC1, which is called a SSN structure.

By virtue of the SSN structure, it is possible to prevent a bridge between capacitors in some cases, and thus to increase capacitance. Here, the second storage node contact SNC2 is defined such that it has a greater width than the first storage node contact SNC1 so as to connect the first storage node contact SNC1 to the storage node SN.

FIG. 1A is a plan view of a typical configuration of a first storage node contact, a second storage node contact and a storage node. Referring to FIG. 1A, the second storage node contact SNC2 connected to the first storage node contact SNC1 has a large width so that a space S between two adjacent second storage node contacts SNC2 becomes narrow. The storage node SN is formed over the second storage node contact SNC2. In this typical configuration, however, the space S between two adjacent second storage node contacts SNC2 is too narrow, thus leading to an electrical bridge.

FIG. 1B is a micrographic view of a typical SSN structure in which an electrical bridge occurs. In FIG. 1B, it can be observed that a bridge A occurs between adjacent second storage node contacts SNC2.

### SUMMARY OF THE INVENTION

Embodiments of the present invention are directed to provide a semiconductor device capable of preventing a bridge between adjacent second storage node contacts while adopting a shifted storage node (SSN) structure for preventing a bridge between capacitors.

In accordance with an aspect of the present invention, there is provided a method for fabricating a semiconductor device. The method includes preparing a substrate provided with a first storage node contact, forming a second storage node contact over the first storage node, the second storage node contact leaning to one side, and forming a storage node of a capacitor over the second storage node.

In accordance with another aspect of the present invention, there is provided a semiconductor device. The device includes a substrate provided with a first storage node contact, a second storage node contact disposed over the first storage node contact, and leaning to one side, and a storage node of a capacitor over the second storage node contact.

### BRIEF DESCRIPTION OF THE DRAWINGS

FIG. 1A is a plan view of a typical configuration of a first storage node contact, a second storage node contact and a storage node.

FIG. 1B is a micrographic view of a typical SSN structure in which an electrical bridge occurs.

FIGS. 2A to 2G are cross-sectional views of a method for fabricating a semiconductor device in accordance with a first embodiment of the present invention.

FIG. 3 is a plan view of a configuration of a first storage node contact, a second storage node contact and a storage node in accordance with the first embodiment of the present invention.

FIG. 4A is a cross-sectional view of a semiconductor device in accordance with a second embodiment of the present invention.

FIG. 4B is a plan view of a configuration of a first storage node contact, a second storage node contact and a storage node in accordance with the second embodiment of the present invention.

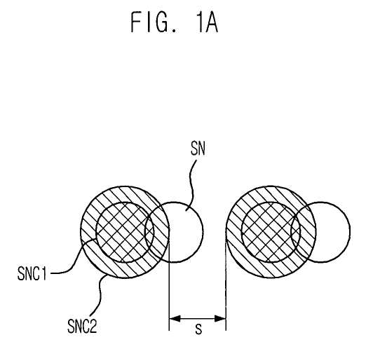

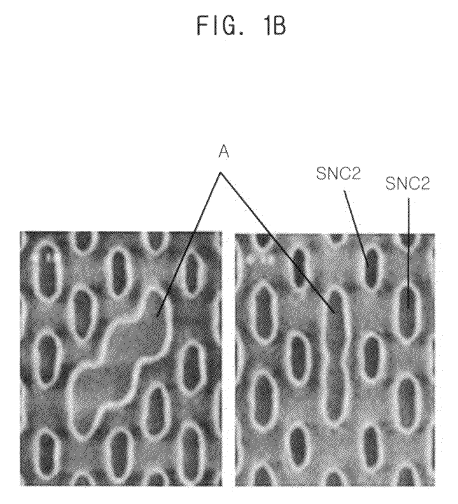

### DESCRIPTION OF SPECIFIC EMBODIMENTS

Embodiments of the present invention relate to a semiconductor device with a storage node contact and a method for fabricating the same. In the drawings, the dimensions of layers and regions are exaggerated for clarity of illustration. It will also be understood that when a layer is referred to as being ‘on’ another layer or substrate, it can be directly on the other layer or substrate, or intervening layers may also be present. Like reference numerals refer to like elements throughout.

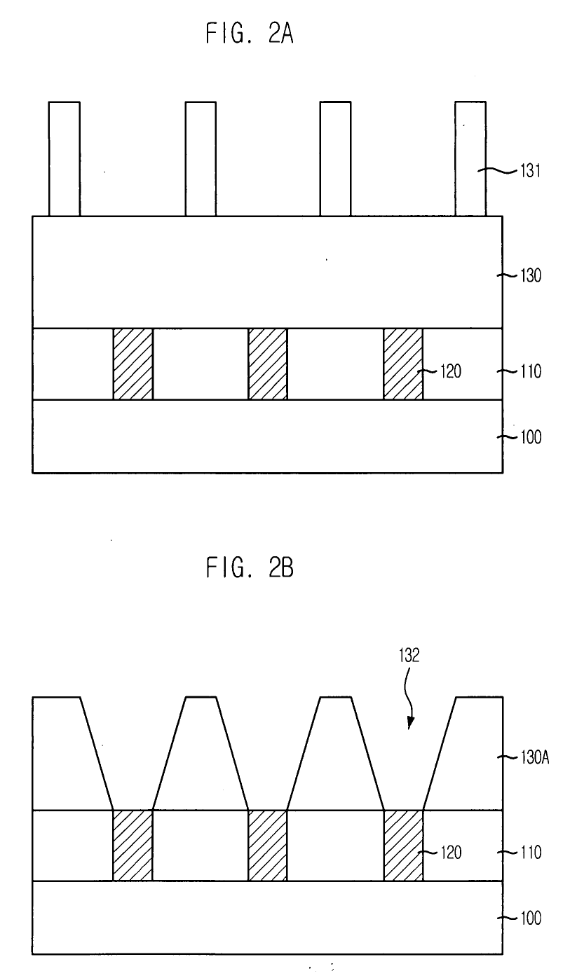

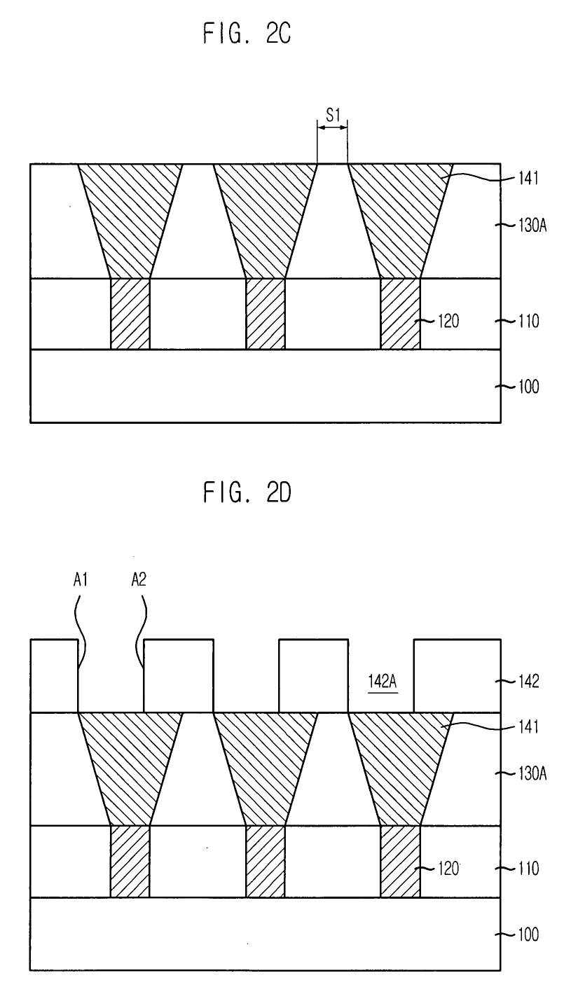

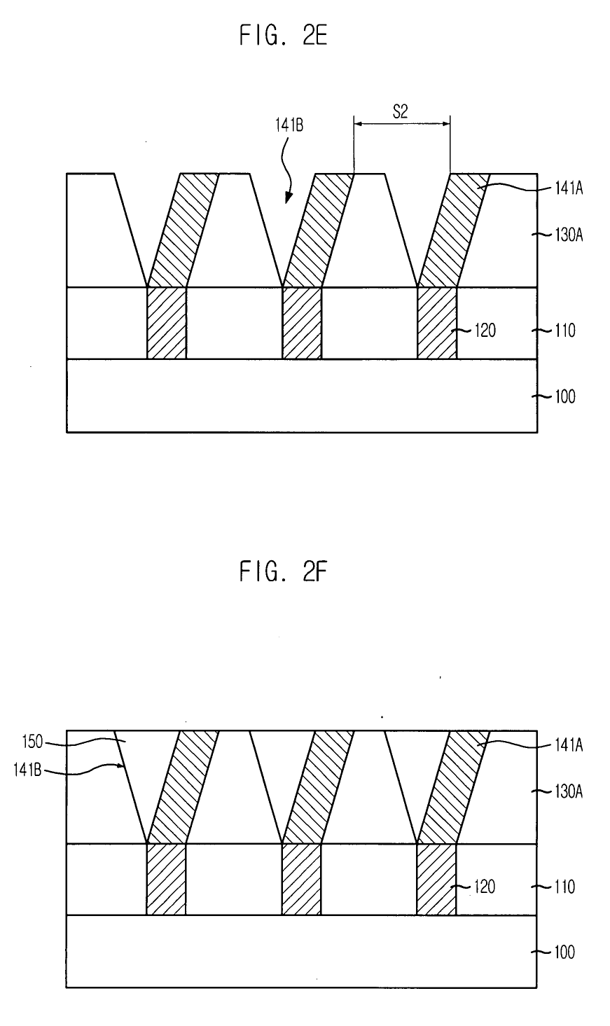

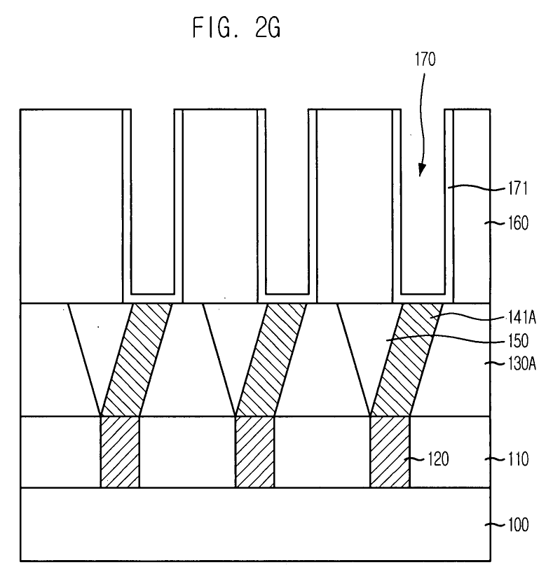

FIGS. 2A to 2G are cross-sectional views of a method for fabricating a semiconductor device in accordance with a first embodiment of the present invention. Referring to FIG. 2A, a first interlayer dielectric (ILD) layer 110 is formed over a substrate 100 where various components for a semiconductor device, e.g., wells, transistors and bit lines, are formed. The first ILD layer 110 includes one oxide layer selected from a group consisting of a boron phosphorus silicate glass (BPSG), a phosphorus silicate glass (PSG), an undoped silicate glass (USG), a tetra ethyl ortho silicate (TEOS), a spin on glass (SOG) and a spin on dielectric (SOD) layers. Materials for use in the first ILD layer 110 are not limited to them, and thus an inorganic or organic-based low-dielectric-constant material as well as an oxide-based material may be used as the first ILD layer 110. In the case of using a landing plug contact (LPC), the substrate 100 may be a landing plug contact.

The first ILD layer 110 is selectively etched to form a contact hole exposing a portion of the substrate 100, and a first storage node contact SNC1 120 is then formed to fill the contact hole. The first storage node contact 120 may include a conductive layer containing silicon, e.g., a polysilicon, an amorphous silicon, a selective epitaxial grown (SEG) silicon, and a conductive layer such as a metal layer.

A second ILD layer 130 is formed over the first ILD layer 110 where the first storage node contact 120 is formed. The second ILD layer 130 may be formed of the same material as the first ILD layer 110. Alternatively, the second ILD layer 130 may be provided with two kinds of material having different etching properties.

A photoresist layer (not shown) is formed over the second ILD layer 130, and then patterned into a certain shape through exposure and development processes, thus forming a first photoresist pattern 131 over the second ILD layer 130. The first mask pattern 131 serves as a contact mask for forming a second storage node contact. The first mask pattern 131 defines an etching region of the second ILD layer 130 such that a second storage node contact will be formed wider than the first storage node contact 120.

Referring to FIG. 2B, the second ILD layer 130 is etched using the first mask pattern 131 as an etch mask, thereby forming a second ILD pattern 130A and a contact hole 132 exposing the first storage node contact 120. If the second ILD layer 130 is an oxide layer, it is preferable that the etching is performed through a slope etch using a gas mixture including fluoroform (CHF₃) gas, tetrafluoromethane (CF₄) gas and argon (Ar) gas. As a result, sidewalls of the contact hole 132 may be inclined downward so that the area of the contact hole gradually decreases toward the bottom. It is preferable that the bottom area of the contact hole 132 is equal to or greater than the top area of the first storage node contact 120. Further, it is preferable that the sidewall of the contact hole 132 is inclined at an angle ranging from approximately 45° to approximately 80° with respect to the surface of the second ILD pattern 130. If the angle is less than this range, a bridge may occur between adjacent contact holes 132. On the contrary, if the angle is greater than this range, a bridge may occur between capacitors to be provided over the contact holes 132. In addition to this angle range, other angles are available if it is possible to prevent a bridge between the contact holes 132 and a bridge between the capacitors as well.

Referring to FIG. 2C, a conductive layer (not shown) is formed over a resultant structure, and then planarized to form a conductive pattern 141 filling the contact hole 132. The conductive pattern 141 includes, for example, a polysilicon layer. Alternatively, the conductive pattern 141 includes a conductive layer containing silicon such as amorphous silicon and SEG silicon, or a metal layer. Preferably, the planarization of the conductive layer is performed using a chemical mechanical polishing (CMP) process or a blanket etching process such as etch-back. In particular, the CMP process is performed such that the polishing is stopped at the second ILD pattern 130A formed of oxide, thus facilitating to perform a subsequent photolithographic process for forming a second mask pattern.

Resultingly, the conductive pattern 141 of which the top area is greater than the bottom area is formed over the first storage node contact 120. Therefore, there is a great possibility that a bridge occurs between the conductive patterns 141 due to a very narrow space S1 therebetween. Herein, the conductive pattern 141 has a similar shape to that of the second storage node contact SNC2 in the typical SSN structure. In the present invention, however, the following processes are performed on the conductive pattern 141 to prevent the bridge caused by the narrow space between the conductive patterns 141.

Referring to FIG. 2D, a second mask pattern 142 is formed over the second ILD pattern 130A and a portion of the conductive pattern 141. It is preferable that the second mask pattern 142 is formed of photoresist like the first mask pattern 131 as described above.

The second mask pattern 142 has an opening 142A with a certain width. One side A1 of the opening 142A is aligned with one side of the conductive pattern 141 and the other side A2 of the opening 142A is aligned in the middle of the conductive pattern 141. For example, as shown in FIG. 2D, the one side A1 of the opening 142A is aligned with a left side of the conductive pattern 141, and the other side A2 is aligned in the middle of the conductive pattern 141.

Referring to FIG. 2E, a portion of the conductive pattern 141 is etched using the second mask pattern 142 as an etch mask. Specifically, a slope etch is performed on the conductive pattern 141 so that the conductive pattern 141 is slantly etched like a ‘V’. For achieving a slope etch, it is preferable that the etching process is performed using a a gas mixture including chlorine (Cl₂) gas, boron trichlorid (BCl₃) gas and sulfur hexafluoride (SF₆) gas if the conductive pattern 141 is formed of polysilicon.

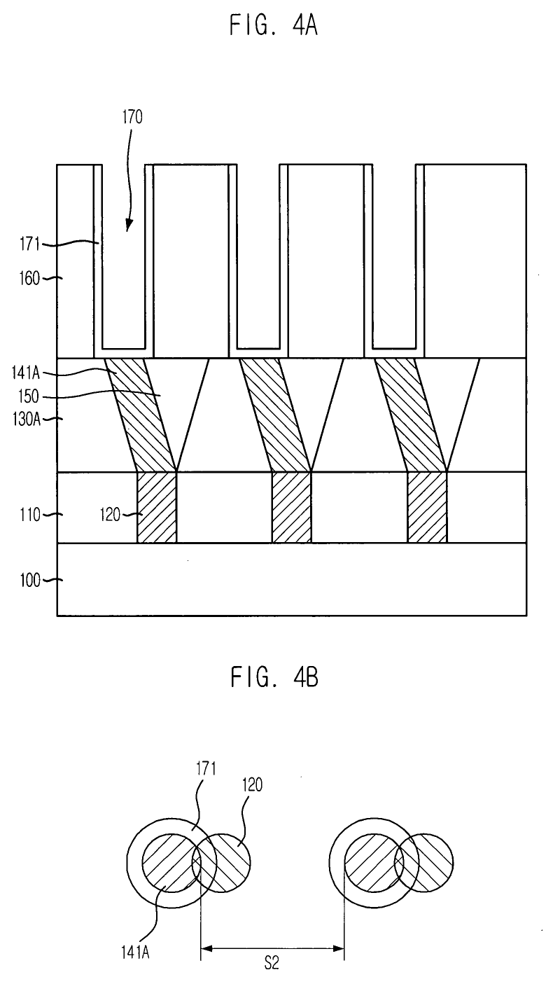

As a result, a second storage node contact 141A, i.e., a leaning storage node contact SNC2, is formed. The second storage node contact 141A is still connected to the first storage node contact 120 disposed thereunder. Although the second storage node contact 141A leans to the right in the drawings, it may lean to the left by adjusting the position of the second mask pattern 142. A recess 141B is formed at the left side of the second storage node contact 141A. The second storage node contact 141A leaning to the left is illustrated in FIG. 4. Thereafter, the second mask pattern 142 is removed.

After the removal of the second mask pattern 142, it can be appreciated that a space S2 between the second storage node contacts 141A becomes wider than the space S1 between the conductive patterns 141 (see FIG. 2C). Therefore, a bridge between the second storage node contacts 141A can be prevented. The increase of the space between the second storage node contacts 141A is ascribed to the decrease in the top width thereof. If the top width of the second storage node contact 141A is reduced, it may be difficult to connect a storage node to the second storage node contact 141A. However, because the semiconductor device of the present invention adopts an SSN structure enabling the storage node to be shifted, the connection can be possible by shifting the storage node such that it can be connected to the leaning second storage node contact 141A.

As described above, the first storage node contact 120 is vertically shaped and has the top area equal to the bottom area. In comparison with the first storage node contact 120, the second storage node contact 141A also has the top area equal to the bottom area but leans to one side. In this way, it is possible to prevent the bridge between the second storage node contacts by forming the second storage node contact 141A leaning to the one side.

In addition, since the second storage node contact 141A leans to the one side, there is no limitation in aligning the second storage node contact 141A during a subsequent forming process of a storage node. Accordingly, it is possible to design various storage node layouts and further prevent layout misalignment between overlying and underlying layers of the first storage node contact, the second storage node contact and the storage node.

Referring to FIG. 2F, a third ILD layer 150 is formed to fill the recess 141B. The third ILD layer 150 may be formed of the same material used in the first and the second ILD layers 110 and 130, but not limited to them. That is, the third ILD layer 150 may be formed of a material different from those of the first and the second ILD layers 110 and 130.

To fill the third ILD layer 150 only into the recess 141B, a planarization process may be performed. It is preferable that the planarization may be performed using a CMP process or a blanket etching process such as an etch-back.

Referring to FIG. 2G, a fourth ILD layer 160 is formed over the third ILD layer 150 and the second ILD layer 130. An etch stop layer (not shown) formed of nitride-based material may be formed in advance under the fourth ILD layer 160.

The fourth ILD layer 160 may be formed of the same material used in the first through third ILD layers 110, 130 and 150, but not limited to them. Alternatively, the fourth ILD layer 160 may be formed of a material different from those of the first through third ILD layers 110, 130 and 150. It is preferable that the thickness of the fourth ILD layer 160 may be appropriately adjusted depending on the required capacitance of a capacitor.

The fourth ILD layer 160 is etched to form an opening 170 exposing the second storage node contact 141A, and the storage node 171 is formed in the opening 170. The storage node 171 may be formed of a polysilicon (poly-Si), a tungsten (W), a titanium (Ti), a tungsten nitride (WN) material or a titanium nitride (TiN) material. The storage node 171 is connected to the second storage node contact 141A disposed thereunder.

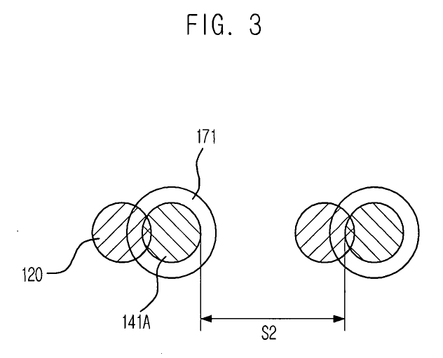

FIG. 3 is a plan view of a configuration of a first storage node contact, a second storage node contact and a storage node in accordance with the first embodiment of the present invention.

Referring to FIG. 3, it can be observed that the space S2 between the second storage node contacts 141A increases because the second storage node contact 141A connected to the first storage node contact 120 leans to one side. The storage node 171 is formed over the second storage node contact 141A.

In conclusion, a bridge between the second storage node contacts can be prevented by virtue of the broad space S2 between the second storage node contacts 141A. Therefore, a bridge between the storage nodes 171 can also be prevented.

FIG. 4A is a cross-sectional view of a semiconductor device in accordance with a second embodiment of the present invention.

FIG. 4B is a plan view of a configuration of a first storage node contact, a second storage node contact and a storage node in accordance with the second embodiment of the present invention.

Unlike the first embodiment, the storage node contact 141A leans to the left in the second embodiment. Herein, like reference numerals denote like elements of the first embodiment. That is, the second embodiment is different from the first embodiment in a leaning direction of the second storage node.

In accordance with the present invention, a sectional area of a second storage node contact can be reduced by forming a leaning storage node contact SNC2 contacting a storage node of a capacitor. Further, the space between adjacent second storage node contacts can be increased, thus preventing a bridge therebetween.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method for fabricating a semiconductor device, the method comprising:
preparing a substrate provided with a first storage node contact;
forming a second storage node contact over the first storage node contact, the second storage node contact leaning to one side; and
forming a storage node of a capacitor over the second storage node contact.

2. The method of claim 1, wherein forming the second storage node contact comprises:
forming a first insulation layer over the substrate;
etching the first insulation layer to form a contact hole of which an area gradually decreases toward a bottom;
forming a conductive pattern filling the contact hole;
etching a portion of the conductive pattern to form a second storage node contact leaning to one side; and
forming a second insulation layer filling a recess which is formed by the second storage node contact leaning to the one side.

3. The method of claim 2, wherein forming the contact hole and the etching the portion of the conductive pattern are performed using a slope etch process.

4. The method of claim 3, wherein, in forming the contact hole, the first insulation layer includes an oxide layer, and the slope etch of the oxide layer is performed using a gas mixture including fluoroform (CHF₃) gas, tetrafluoromethane (CF₄) gas, and argon (Ar) gas.

5. The method of claim 3, wherein, in forming the second storage node contact, the conductive pattern includes polysilicon, and the slope etch of the second storage node contact is performed using a gas mixture including chlorine (Cl₂) gas, boron trichlorid (BCl₃) gas, and sulfur hexafluoride (SF₆) gas.

6. The method of claim 2, wherein the first and the second insulation layers include an oxide layer.

7. The method of claim 1, wherein the first and the second storage node contacts include a polysilicon layer or a metal layer.

8. A semiconductor device, the device comprising:
a substrate provided with a first storage node contact;
a second storage node contact disposed over the first storage node contact, and leaning to one side; and
a storage node of a capacitor over the second storage node contact.

9. The semiconductor device of claim 8, further comprising a first insulation layer supporting the first storage node contact and a second insulation layer supporting the second storage node contact.

10. The semiconductor device of claim 9, wherein the first and the second insulation layers include an oxide layer.

11. The semiconductor device of claim 8, wherein the first and the second storage node contacts include a polysilicon layer or a metal layer.
